(19) United States
(12) Patent Application Publication
(10) Pub. No.: US 2018/0350307 A1
(43) Pub. Date: Dec. 6, 2018

(54) LIGHT-EMITTING DIODE DISPLAY PANEL AND DRIVING METHOD THEREOF

(71) Applicant: InnoLux Corporation, Miao-Li County (TW)

(72) Inventor: Yu-Sheng TSAI, Miao-Li County (TW)

(21) Appl. No.: 15/972,276

(22) Filed: May 7, 2018

(30) Foreign Application Priority Data
Jun. 1, 2017 (CN) 201710404088.7

(51) Int. Cl. G09G 3/3291; H01L 51/50; G09G 3/3233; G09G 3/3258; G09G 3/3283

(52) U.S. Cl. CPC G09G 3/3291; H01L 51/5012; G09G 3/3283; G09G 3/3258; G09G 3/3233

(57) ABSTRACT

The present disclosure provides a light-emitting diode display panel and the driving method thereof. Data transistor includes control terminal connected to first control signal source, first terminal connected to data line, and second terminal. Driving transistor includes control terminal, first terminal, and second terminal connected to high voltage source. Storage capacitor is connected to data and driving transistors. Compensating transistor includes control terminal connected to first control signal source, first terminal connected to control terminal of driving transistor, and second terminal connected to second control signal source. First control transistor includes control terminal connected to third control signal source, first terminal connected to second terminal of the data transistor, and second terminal connected to control terminal of driving transistor. Second control transistor includes control terminal connected to third control signal source, first terminal connected to organic light-emitting diode element, and second terminal connected to first terminal of driving transistor.

### BACKGROUND

### 1. Field of the Disclosure

The present disclosure is related to the field of display device, and more specifically, the present disclosure is related to a LED display panel and the driving method thereof.

### 2. Description of Related Art

Driving transistors for the pixels in active matrix light-emitting diodes (AM-LED) can be divided into P-type and N-type according to the fabrication technique of the back plate. For conventional N-type driving transistor, threshold voltage deviation tends to occur in the driving transistor. In other words, the threshold voltage (Vt) for N-type driving transistor may vary locally because of fabrication process. That is to say, for two N-type driving transistors of the same size, when the same driving voltage is applied thereto, the output currents from the driving transistors may not be the same as each other, thereby causing problems such as uneven brightness (mura) or bad uniformity. Hence, conventional LED display panels still have plenty of room for improvement.

### SUMMARY

To this aim, the present disclosure provides a LED display panel and the driving method thereof. During the illumination period, the current of the driving transistor is not dependent on the threshold voltage thereof, and therefore, the current of the driving transistor is not affected by the variation of the threshold voltage. For two driving transistors of the same size, when the same driving voltage is applied thereto, the output currents from the driving transistors may be the same as each other, thereby solving problems such as uneven brightness (mura) or bad uniformity.

According to one aspect of the present disclosure, a LED display panel is provided, which may be disposed with a plurality of pixel circuitries. At least one pixel circuitry may include a data transistor, a driving transistor, a storage capacitor, a compensating transistor, a first control transistor, and a second control transistor. The data transistor may include a control terminal connected to a first control signal source, a first terminal connected to a data line, and a second terminal. The driving transistor may include a control terminal, a first terminal, and a second terminal connected to a high voltage source. The storage capacitor may be connected to the second terminal of the data transistor and the first terminal of the driving transistor. The compensating transistor may include a control terminal connected to the first control signal source, a first terminal connected to the control terminal of the driving transistor, and a second terminal connected to a second control signal source. The first control transistor may include a control terminal connected to a third control signal source, a first terminal connected to the second terminal of the data transistor, and a second terminal connected to the control terminal of the driving transistor. The second control transistor may include a control terminal connected to third control signal source, a first terminal connected to a light-emitting diode element, and a second terminal connected to the first terminal of the driving transistor.

According to another aspect of the present disclosure, a LED display panel is further provided, which may be disposed with a plurality of pixel circuitries. At least one pixel circuitry may include a data transistor, a driving transistor, a compensating transistor, a first control transistor, a storage capacitor, a second control transistor, and a reset transistor. The data transistor may include a control terminal connected to a first control signal source, a first terminal, and a second terminal connected to a data line. The driving transistor may include a control terminal connected to the first terminal of the data transistor, a first terminal, and a second terminal connected to a high voltage source. The compensating transistor may include a control terminal connected to the first control signal source, a first terminal connected to a reference signal, and a second terminal. The first control transistor may include a control terminal connected to a second control signal source, a first terminal connected to the second terminal of the compensating transistor, and a second terminal connected to the control terminal of the driving transistor. The storage capacitor may be connected to the second terminal of the compensating transistor and the first terminal of the driving transistor. The second control transistor may include a control terminal connected to the second control signal source, a first terminal connected to a light-emitting diode element, and a second terminal connected to the first terminal of the driving transistor. The reset transistor may include a control terminal connected to a third control signal source, a first terminal connected to a low voltage source, and a second terminal connected to the first terminal of the driving transistor.

According to yet another aspect of the present disclosure, a method for driving the LED display panel is provided. The LED display panel may be disposed with a plurality of pixel circuitries. The pixel circuitries may be arranged in rows and columns to form a plurality of regions. The method may use a first control signal source, a second control signal source, a third control signal source, and a fourth control signal source to control each pixel circuitry. The first control signal source, the second control signal source, the third control signal source, and the fourth control signal source may generate relevant control time sequence respectively, and each pixel circuitry has a reset period, a compensation period, and an illumination period. The reset period, the compensation period, and the illumination period may operate independently, and during the compensation period, the storage capacitor in each pixel circuitry may be charged with the voltage for displaying data, threshold voltage of the driving transistor, or high adjusting voltage of the control signal.

Other objects, advantages, and novel features of the disclosure will become more apparent from the following detailed description when taken in conjunction with the accompanying drawings.

### BRIEF DESCRIPTION OF THE DRAWINGS

FIG. 1 is a schematic diagram of the of the light-emitting diode (LED) display panel of the present disclosure;

FIG. 2 is a circuit diagram of the pixel circuitry of the present disclosure;

FIG. 3 is a schematic diagram of the reset period of the pixel circuitry of the present disclosure;

FIG. 4 is a schematic diagram of the compensation period of the pixel circuitry of the present disclosure;

FIG. 5 is a schematic diagram of the illumination period of the pixel circuitry of the present disclosure;

FIG. 6 is another circuit diagram of the pixel circuitry of the present disclosure;

FIG. 7 is another circuit diagram of the pixel circuitry of the present disclosure;

FIG. 8 is a schematic diagram of the reset period of the pixel circuitry of FIG. 7 of the present disclosure;

FIG. 9 is a schematic diagram of the compensation period of the pixel circuitry of FIG. 7 of the present disclosure;

FIG. 10 is a schematic diagram of the illumination period of the pixel circuitry of FIG. 7 of the present disclosure; and

FIG. 11 is a flowchart for the driving method of the LED display panel of the present disclosure.

### DETAILED DESCRIPTION OF THE PREFERRED EMBODIMENT

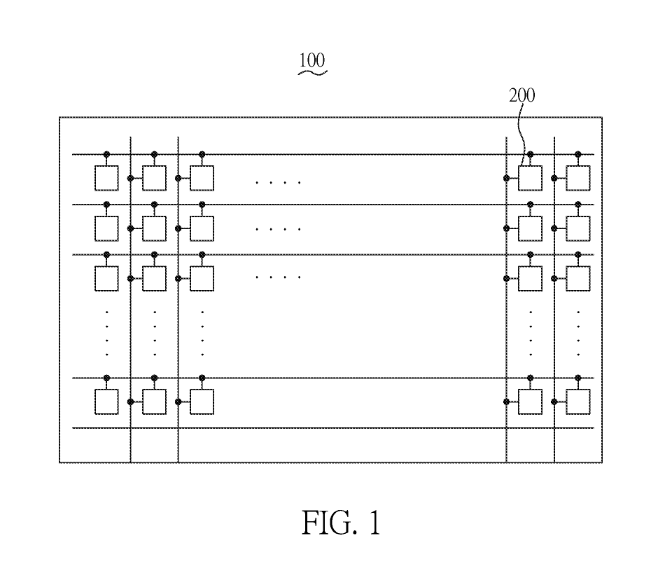

FIG. 1 is a schematic diagram of the of the light-emitting diode (LED) display panel of the present disclosure. The LED display panel 100 may be disposed with a plurality of pixel circuitries 200 and wirings that correspond to each other and are electrically connected; the pixel circuitries 200 may be arranged in rows and columns to form a plurality of regions. The pixel circuitries 200 may be adapted to drive the corresponding light-emitting diode elements to display image. In an embodiment of the present disclosure, the light-emitting diode element may be, but not limited to, organic light-emitting diode ((SLED). In some embodiments, the light-emitting diode element may be an inorganic light-emitting diode (LED), a quantum dot light-emitting diode (QLED), or other self-illuminating light-emitting diodes.

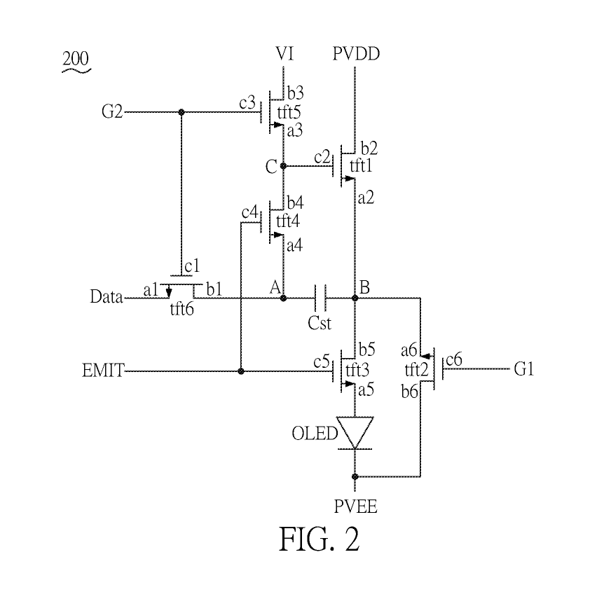

FIG. 2 is a circuit diagram of the pixel circuitry of the present disclosure. As shown in FIG. 2, the pixel circuitry 200 may include a data transistor tft6, a driving transistor tft1, a storage capacitor Cst, a compensating transistor tft5, a first control transistor tft4, a second control transistor tft3, and a reset transistor tft2. Although the light-emitting diode element OLED in FIG. 2 is illustrated as an organic light-emitting diode, the present disclosure is not limited thereto.

As illustrated in FIG. 2, the data transistor tft6 may include a control terminal c1, a first terminal a1, and a second terminal b1. Particularly, the control terminal c1 may be connected to the first control signal source G2, and the first terminal a1 may be connected to the data line Data. The driving transistor tft1 may include a control terminal c2, a first terminal a2, and a second terminal b2. The second terminal b2 may be connected to the high voltage source PVDD. The storage capacitor Cst may be connected to the second terminal b1 of the data transistor tft6 and the first terminal a2 of the driving transistor tft1. In other words, the storage capacitor Cst may be connected between node A and node B.

The compensating transistor tft5 may include a control terminal c3, a first terminal a3 and a second terminal b3. More specifically, the control terminal c3 may be connected to the first control signal source G2, the first terminal a3 may be connected to the control terminal c2 of the driving transistor tft1, and the second terminal b3 may be connected to the second control signal source VI. The first control transistor tft4 may include a control terminal c4, a first terminal a4 and a second terminal b4. Particularly, the control terminal c4 may be connected to the third control signal source EMIT, the first terminal a4 may be connected to the second terminal b1 of the data transistor tft6, and the second terminal b4 may be connected to the control terminal c2 of the driving transistor tft1.

The second control transistor tft3 may include a control terminal c5, a first terminal a5, and a second terminal b5. The control terminal c5 may be connected to the third control signal source EMIT, the first terminal a5 may be connected to an organic light-emitting diode element OLED (emitting layer comprises organic light-emitting material), and the second terminal b5 may be connected to the first terminal a2 of the driving transistor tft1. The reset transistor tft2 may include a control terminal c6, a first terminal a6 and a second terminal b6. More specifically, the control terminal c6 may be connected to the fourth control signal source G1, the first terminal a6 may be connected to the first terminal a2 of the driving transistor tft1, and the second terminal b6 may be connected to the low voltage source PVEE.

As shown in FIG. 2, the data transistor tft6, the driving transistor tft1, the compensating transistor tft5, the first control transistor tft4, the second control transistor tft3, and the reset transistor tft2 may all be N-type transistors. The semiconductor material for the data transistor tft6, the driving transistor tft1, the compensating transistor tft5, the first control transistor tft4, the second control transistor tft3, and the reset transistor tft2 may be N-type Low Temperature Poly-silicon (LTPS), N-type Indium Gallium Zinc Oxide (IGZO), or N-type Amorphous Silicon, but the present disclosure is not limited thereto.

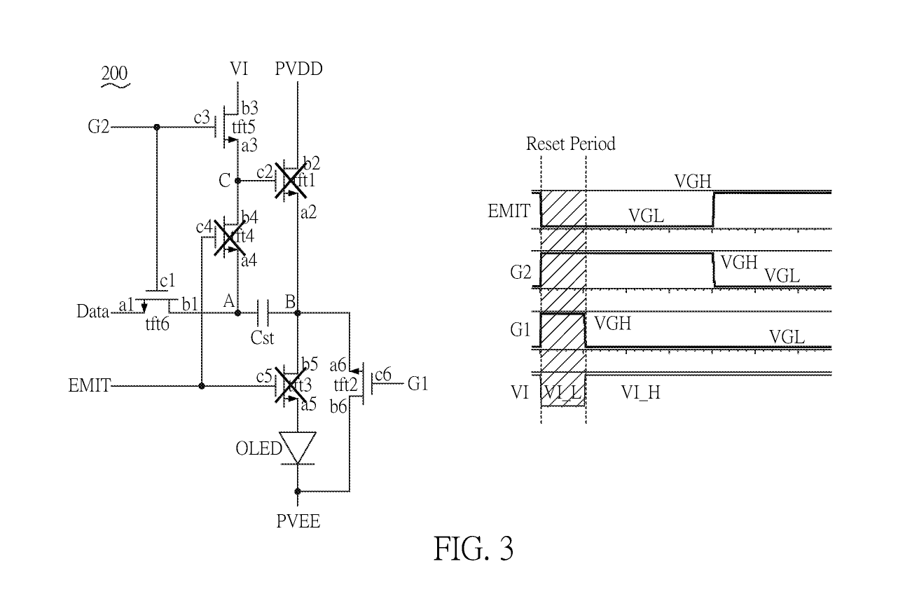

FIG. 3 is a schematic diagram of the reset period of the pixel circuitry of the present disclosure. Referring to FIG. 3, during a reset period, the first control signal source G2 may output a high control voltage VGH, the second control signal source VI may output a low adjusting voltage VI_L, the third control signal source EMIT may output a low control voltage VGL, and the fourth control signal source G1 may output the high control voltage VGH. The high control voltage VGH may be higher than the voltage of the high voltage source PVDD. The low adjusting voltage VI_L may be higher than the voltage of the low voltage source PVEE. The low voltage source PVEE may be higher than the voltage of the low control voltage VGL.

During the reset period, since the first control signal source G2 outputs the high control voltage VGH and the fourth control signal source G1 outputs the high control voltage VGH, the data transistor tft6, the compensating transistor tft5, and the reset transistor tft2 may be turned on, and voltages at both terminals of the storage capacitor Cst may respectively be Vdata and PVEE, where Vdata is a voltage for a display data written by the data line Data, and PVEE is a voltage of the low voltage source. In other words, the voltage at node A is Vdata while the voltage at node B is PVEE.

Because the third control signal source EMIT outputs low control voltage VGL, the first control transistor tft4 and the second control transistor tft3 may be turned off. The compensating transistor tft5 may be turned on, and the voltage at node C may be the low adjusting voltage VI_L. In order to turn off the driving transistor tft1, the low adjusting voltage VI_L has to be low, so as to prevent current leakage from occurring in the organic light-emitting diode element OLED. In one embodiment, the value of the low adjusting voltage VI_L has to be lower than the sum of the low voltage source voltage PVEE and the threshold voltage Vt1 of the driving transistor tft1. During the reset period, there is no electrical path inside the organic light-emitting diode element OLED, and hence, dark-state light leakage and power consumption issues of the organic light-emitting diode element OLED can be avoided. The low adjusting voltage VI_L is higher than the low control voltage VGL, and the low adjusting voltage VI_L is lower than the sum of voltage of the low voltage source PVEE and the threshold voltage Vt1 of the driving transistor tft1 So, the low adjusting voltage VI_L satisfies the relationship VGL<VI_L<PVEE±Vt1.

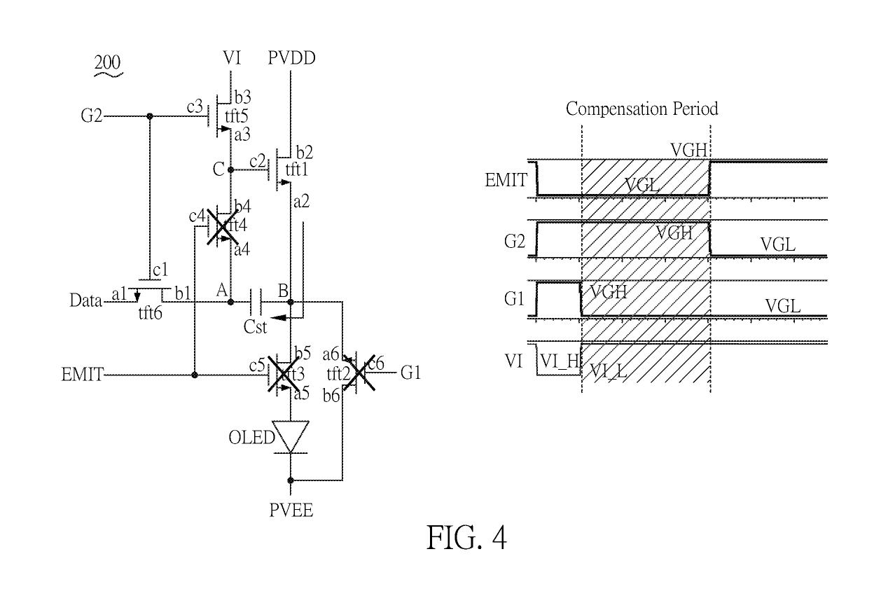

FIG. 4 is a schematic diagram of the compensation period of the pixel circuitry of the present disclosure. Referring to FIG. 4, during a compensation period, the first control signal source G2 may output the high control voltage VGH, the second control signal source VI may output a high adjusting voltage VI_H, the third control signal source EMIT may output a low control voltage VGL, and the fourth control signal source G1 may output the low control voltage VGL. The high voltage source PVDD may be higher than the high adjusting voltage VI_H.

During the compensation period, since the first control signal source G2 outputs the high control voltage VGH, the compensating transistor tft5 and the data transistor tft6 may be turned on. Because the third control signal source EMIT outputs low control voltage VGL, the first control transistor tft4 and the second control transistor tft3 may be turned off. The fourth control signal source G1 may output the low control voltage VGL, and the reset transistor tft2 may be turned off. The compensating transistor tft5 may be turned on and the first control transistor tft4 may be turned off; therefore the voltage at node C is the high adjusting voltage Vl_H, and this causes the driving transistor tft1 to be turned on. The voltage at node B is Vl_H−Vt1, where Vl_H is the high adjusting voltage of the second control signal source Vl, and Vt1 is the threshold voltage of the driving transistor tft1. Since the data transistor tft6 is turned on, the voltage at node A is Vdata. Therefore, the voltages at both sides of the storage capacitor Cst are Vdata and VI_H−Vt1 respectively. In other words, the voltage in the storage capacitor Cst is Vdata−VI_H+Vt1.

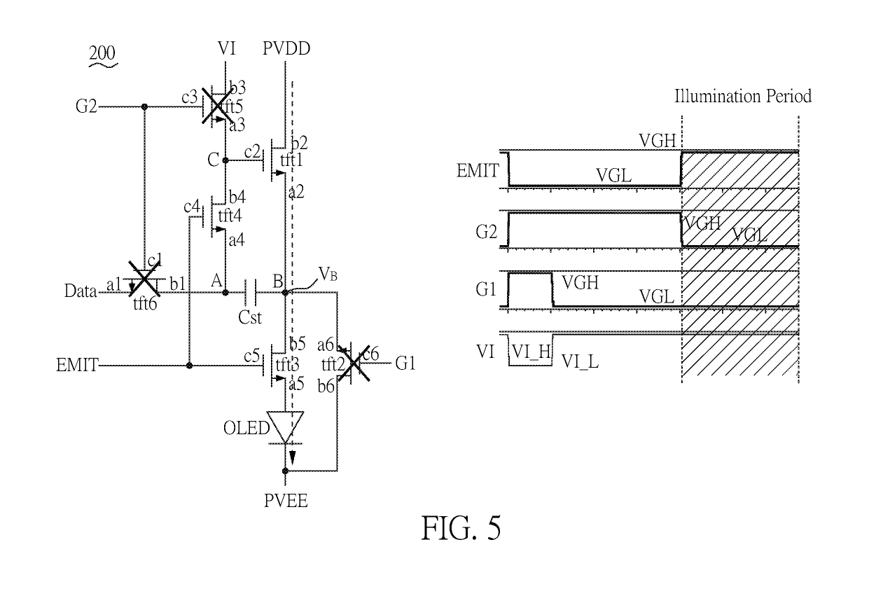

FIG. 5 is a schematic diagram of the illumination period of the pixel circuitry of the present disclosure. Referring to FIG. 5, during a illumination period, the first control signal source G2 may output the low control voltage VGL, the second control signal source VI may output a high adjusting voltage VI_H, the third control signal source EMIT may output a high control voltage VGH, and the fourth control signal source G1 may output the low control voltage VGL.

During the illumination period, since the first control signal source G2 outputs the low control voltage VGL, the compensating transistor tft5 and the data transistor tft6 may be turned off. The fourth control signal source G1 may output the low control voltage VGL, and the reset transistor tft2 may be turned off. Because the third control signal source EMIT outputs low control voltage VGL, the first control transistor tft4 and the second control transistor tft3 may be turned on. Since the first control transistor tft4 is turned on, the voltage at node C may equal to the voltage at node A, and the driving transistor tft1 may be turned on.

During this time, an electrical path is formed between the high voltage source PVDD and the low voltage source PVEE. The voltage at node B is determined by the resistance of the driving transistor tft1, the second control transistor tft3 and the organic light-emitting diode element OLED. The voltage at node B is labeled as V_{B}, and V_{B}=[(PVDD−PVEE)*(R2+R3)/(R1+R2+R3)]+PVEE, where PVDD is the output voltage of the high voltage source PVDD, PVEE is the output voltage of the low voltage source PVEE, R1 is the resistance of the driving transistor tft1 while the driving transistor tft1 is turned on, R2 is the resistance of the second control transistor tft3 while the second control transistor tft3 is turned on, and R3 is the resistance of the organic light-emitting diode element OLED while the organic light-emitting diode element OLED is turned on. Since the voltage at the driving transistor tft1 and the second control transistor tft3 can be regarded as constant, and since R1 is significantly larger than R2, the voltage V_{B} at node B can be regarded as approximately the voltage of the organic light-emitting diode element OLED.

Since the voltage at node A equals to the voltage at node B plus the voltage in the storage capacitor Cst, the voltage at node A is V_{B}+Vdata−VI_H+Vt1. Similarly, the voltage at node C is V_{B}+Vdata−VI_H+Vt1. Therefore, the gate-source voltage Vgs_tft1 of the driving transistor tft1 is the voltage at node C minus the voltage at node B. Hence, the gate-source voltage Vgs_tft1 of the driving transistor is (V_{B}+Vdata−VI_H+Vt1)−V_{B}=Vdata−VI_H+Vt1. In other words, the potential difference between both sides of the storage capacitor is Vdata−VI_H+Vt1. It can be appreciated that the voltage V_{B} at node B does not appear in the equation for the current, and thus does not affect the current.

Therefore, during the illumination period, the current of the driving transistor tft1 is:

I__{^{tft1}}=I__{^{OLED}}=Kpn[Vgs_tft1−Vt1]²=Kpn*[(Vdata−VI_H+Vt1)−Vt1]²=Kpn*[Vdata−VI_H]²,

where Kpn is the transistor transconductance parameter of the driving transistor tft1, Kpn=½*u*Cox*W/L; u is the charge carrier mobility of the semiconductor, Cox is the capacitance per unit area, and W/L is the transistor width-length ratio.

From the equations above, it can be appreciated that during the illumination period, the current I__{^{tft1}} of the driving transistor tft1 is not affected by the threshold voltage Vt1 of the driving transistor tft1. Therefore, the current I__{^{tft1}} of the driving transistor tft1 is not affected by the localized threshold voltage variation that is caused by the fabrication process or any other factors. For two N type driving transistors of the same size, with the technique of the present disclosure, when the same driving voltage is applied thereto, the output currents from the driving transistors may be the same as each other, thereby solving problems such as uneven brightness (mura) or bad uniformity.

Furthermore, according to the equation for current, Vdata is a voltage for a display data written by the data line Data, i.e. Vdata corresponds to the current of the organic light-emitting diode element OLED, or Vdata corresponds to the brightness of the organic light-emitting diode element OLED; therefore, by writing in a voltage value of the display data, the brightness of the organic light-emitting diode element OLED can be changed. In addition, it can be appreciated from the equation for current that the brightness of the organic light-emitting diode element OLED can be changed via the high adjusting voltage VI_H. The high adjusting voltage VI_H is a global parameter. In other words, when the high adjusting voltage VI_H is reduced, the brightness of the LED display panel 100 may be increased; when the high adjusting voltage VI_H is increased, the brightness of the LED display panel 100 may be reduced.

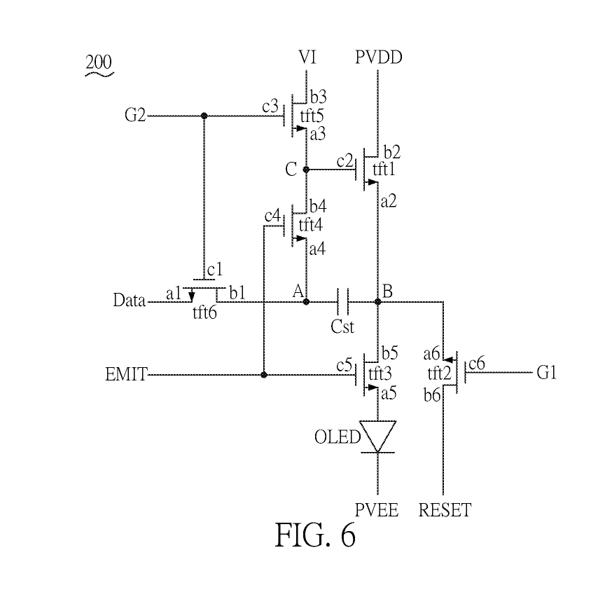

FIG. 6 is another circuit diagram of the pixel circuitry 200 of the present disclosure; the major difference between FIG. 6 and FIG. 2 lies in that the second terminal b6 of the reset transistor tft2 is connected to a reset signal source RESET. Therefore, during the reset period, the value of the low adjusting voltage VI_L has to be lower than the sum of the reset signal source RESET and the threshold voltage Vt1 of the driving transistor tft1, such that the driving transistor tft1 is turned off. Therefore, during the reset period, there is no electrical path inside the organic light-emitting diode element OLED, and hence, dark-state light leakage and power consumption issues of the organic light-emitting diode element OLED can be avoided.

The circuit in FIG. 6 is used to perform circuit simulation, the simulation conditions are: PVDD=4.6V, PVEE=−3.2V, VI_H=4.6V, VI_L=−3.2V, VRESRT=−3.2V, Vdata=0 to 4V, VGH=7V, VGL=−7V, I__{^{tft1}}=47 nA, and Cst=100 fF. When the threshold voltage Vt1 change is 0V, I__{^{tft1}} is 47.7011 nA, and the error is 0.00%. When the threshold voltage Vt1 change is 0.1V, I__{^{tft1}} is 47.3786 nA, and the error is −0.68%. When the threshold voltage Vt1 change is −0.1V, I__{^{tft1}} is 48.1941 nA, and the error is 1.03%.

Another simulation conditions are: PVDD=4.6V, PVEE=−3.2V, VI_H=4.6V, VI_L=−3.2V, VRESRT=−3.2V, Vdata=0 to 4V, VGH=7V, VGL=−7V, I__{^{tft1}}=70 nA, and Cst=100 fF. When the threshold voltage Vt1 change is 0V, I__{^{tft1}} is 70.346 nA, and the error is 0.00%. When the threshold voltage Vt1 change is 0.1V, is 69.6632 nA, and the error is −0.97%. When the threshold voltage Vt1 change is −0.1V, I__{^{tft1}} is 70.9798 nA, and the error is 0.90%.

Another simulation conditions are: PVDD=5.5V, PVEE=−3.2V, VI_H=0.4V, VI_L=−3.2V, VRESRT=−1V, Vdata=0 to 2V, VGH=7V, VGL=−7V, I__{^{tft1}}=40 nA, and Cst=60 fF. When the threshold voltage Vt1 change is 0V, I__{^{tft1}} is 40.592 A, and the error is 0.00%. When the threshold voltage Vt1 change is 0.1V, I__{^{tft1}} is 39.4073 nA, and the error is −2.92%. When the threshold voltage Vt1 change is −0.1V, I__{^{tft1}} is 41.7403 nA, and the error is 2.83%.

It is apparent from the aforementioned data that, although there is error in the current, such error is caused by the leakage of the transistor or the organic light-emitting diode element; alternatively, smaller capacitance of the storage capacitor Cst may magnify the effect of current leakage, thus causing the current error to be larger; the current error will be even higher if the technique of the present disclosure is not employed. Since the threshold voltage Vt1 change is normally less than approximately 0.1V, from the simulation results, it can be shown that, for two N type driving transistors of the same size, with the technique of the present disclosure, when the same driving voltage is applied thereto, the error of output currents may be less than 1%, thereby solving problems such as uneven brightness (mura) or bad uniformity.

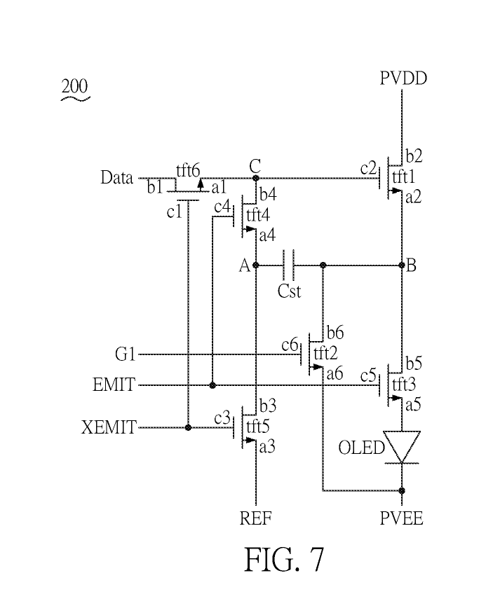

FIG. 7 is a circuit diagram of another pixel circuitry 200 of the present disclosure. As shown in FIG. 7, the pixel circuitry 200 may include a data transistor tft6, a driving transistor tft1, a storage capacitor Cst, a compensating transistor tft5, a first control transistor tft4, a second control transistor tft3, and a reset transistor tft2. Although the light-emitting diode element OLED in FIG. 7 is illustrated as an organic light-emitting diode, the present disclosure is not limited thereto.

As illustrated in FIG. 7, the data transistor tft6 may include a control terminal c1, a first terminal a1, and a second terminal b1. Particularly, the control terminal c1 may be connected to the first control signal source XEMIT, and the second terminal b1 may be connected to the data line Data. The driving transistor tft1 may include a control terminal c2, a first terminal a2, and a second terminal b2. More specifically, the control terminal c2 is connected to the first terminal a1 of the data transistor tft6, and the second terminal b2 is connected to a high voltage source PVDD.

The compensating transistor tft5 may include a control terminal c3, a first terminal a3 and a second terminal b3. Particularly, the control terminal c3 may be connected to the first control signal source XEMIT, and the first terminal a3 may be connected to a reference signal REF. The first control transistor tft4 may include a control terminal c4, a first terminal a4 and a second terminal b4. Particularly, the control terminal c4 may be connected to the second control signal source EMIT, the first terminal a4 may be connected to the second terminal b3 of the compensating transistor tft5, and the second terminal b4 may be connected to the control terminal c2 of the driving transistor tft1. In other words, the second terminal b4 of the first control transistor tft4 may be connected to the control terminal c2 of the driving transistor tft1 through a node C.

The storage capacitor Cst may be connected to the second terminal b3 of the compensating transistor tft5 and the first terminal a2 of the driving transistor tft1. In other words, the storage capacitor Cst may be connected between node A and node B.

The second control transistor tft3 may include a control terminal c5, a first terminal a5, and a second terminal b5. The control terminal c5 may be connected to the second control signal source EMIT, the first terminal a5 may be connected to an organic light-emitting diode element OLED, and a second terminal b5 may be connected to the first terminal a2 of the driving transistor tft1. The reset transistor tft2 may include a control terminal c6, a first terminal a6 and a second terminal b6. In particular, the control terminal c6 may be connected to a third control signal source G1, the first terminal a6 may be connected to a low voltage source PVEE, and the second terminal b6 may be connected to the first terminal a2 of the driving transistor tft1.

As shown in FIG. 7, the data transistor tft6, the driving transistor tft1, the compensating transistor tft5, the first control transistor tft4, the second control transistor tft3, and the reset transistor tft2 may all be N-type transistors. The semiconductor material for the data transistor tft6, the driving transistor tft1, the compensating transistor tft5, the first control transistor tft4, the second control transistor tft3, and the reset transistor tft2 may be N-type Low Temperature Poly-silicon (LTPS), N-type Indium Gallium Zinc Oxide (IGZO), or N-type Amorphous Silicon, but the present disclosure is not limited thereto.

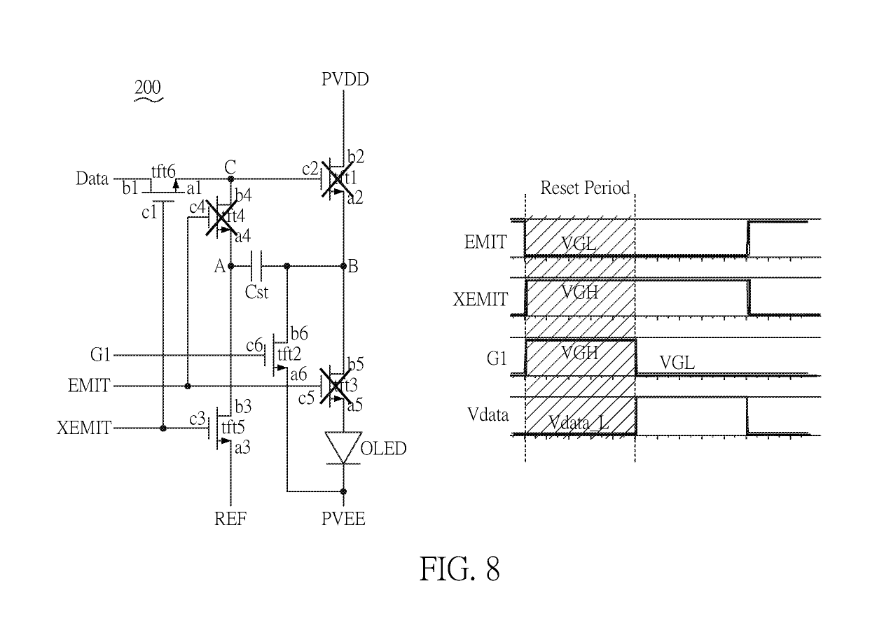

FIG. 8 is a schematic diagram of the reset period of the pixel circuitry 200 of FIG. 7 of the present disclosure. Referring to FIG. 8, during a reset period, the first control signal source XEMIT is a high control voltage VGH, the second control signal source EMIT is a low control voltage VGL, and the third control signal source G1 is the high control voltage VGH. The high control voltage VGH may be higher than the voltage of the high voltage source PVDD. The low voltage source PVEE may be higher than the voltage of the low control voltage VGL.

During the reset period, since first control signal source XEMIT outputs the high control voltage VGH and the third control signal source G1 outputs the high control voltage VGH, the compensating transistor tft5, the data transistor tft6, and the reset transistor tft2 may be turned on, and voltages at both terminals of the storage capacitor Cst may respectively be VREF and PVEE, where VREF is a voltage for reference signal REF, and PVEE is a voltage of the low voltage source PVEE. In other words, the voltage at node A is VREF, the voltage at node B is PVEE, and the voltage at node C is Vdata, where Vdata is a voltage for a display data written by the data line Data. Under the circumstances, Vdata is low data voltage Vdata_L, and the voltage at node C is the low data voltage Vdata_L.

Because the second control signal source EMIT outputs low control voltage VGL, the first control transistor tft4 and the second control transistor tft3 may be turned off. The data transistor tft6 may be turned on, and the voltage at node C may be the low data voltage Vdata_L. In order to turn off the driving transistor tft1, the low data voltage Vdata_L has to be low, so as to prevent current leakage from occurring in the organic light-emitting diode element OLED. In one embodiment, the value of the low voltage source Vdata_L has to be lower than the sum of the low voltage source voltage PVEE and the threshold voltage Vt1 of the driving transistor tft1, so that the driving transistor tft1 is turned off. During the reset period, since there is no electrical path inside the organic light-emitting diode element OLED, dark-state light leakage and power consumption issues of the organic light-emitting diode element OLED can be avoided. The low data voltage Vdata_L is higher than the low control voltage VGL, and the low data voltage Vdata_L is lower than the sum of voltage of the low voltage source PVEE and the threshold voltage Vt1 of the driving transistor tft1. So, the low data voltage Vdata_L satisfies the relationship VGL<Vdata_L<PVEE+Vt1.

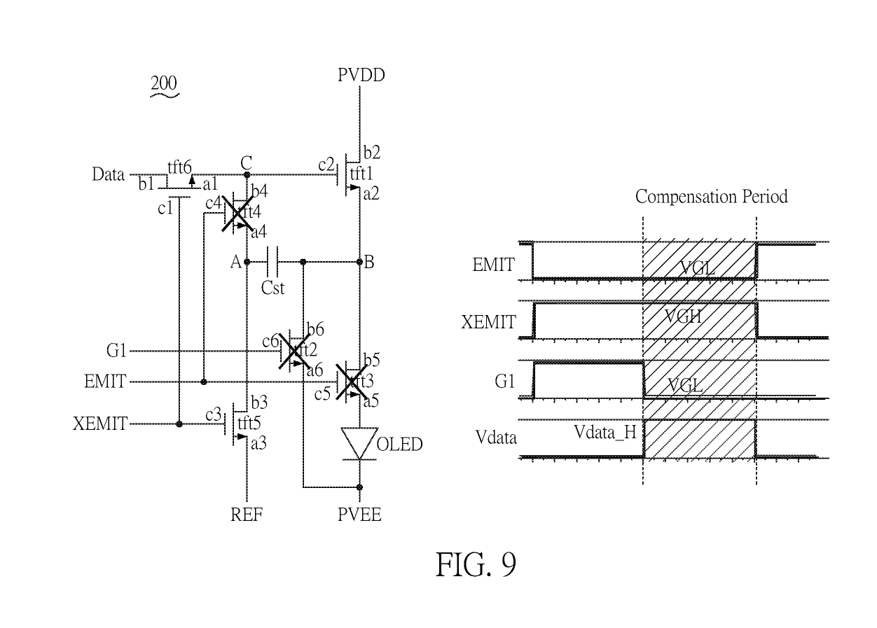

FIG. 9 is a schematic diagram of the compensation period of the pixel circuitry 200 of FIG. 7 of the present disclosure. Referring to FIG. 9, during a compensation period, the first control signal source XEMIT outputs high control voltage VGH, the second control signal source EMIT outputs a low control voltage VGL, and the third control signal source G1 outputs the low control voltage VGL.

During the compensation period, since the first control signal source XEMIT outputs the high control voltage VGH, the compensating transistor tft5 and the data transistor tft6 may be turned on. Because the second control signal source EMIT outputs low control voltage VGL, the first control transistor tft4 and the second control transistor tft3 may be turned off. The third control signal source G1 may output the low control voltage VGL, and the reset transistor tft2 may be turned off.

Since the data transistor tft6 is turned on and the first control transistor tft4 is turned off, the voltage at node C is Vdata, where Vdata is a voltage for a display data written by the data line Data. Under the circumstances, the Vdata is high data voltage Vdata_H, and the voltage at node C is the high data voltage Vdata_H; hence the driving transistor tft1 is turned on. The voltage at node B is Vdata_H−Vt1, where Vdata_H is the voltage of the high data voltage Vdata_H, and Vt1 is the threshold voltage of the driving transistor tft1 Since the compensating transistor tft5 is turned on, the voltage at node A is VREF. Therefore, the voltages at both sides of the storage capacitor Cst are VREF and Vdata_H−Vt1 respectively. In other words, the voltage in the storage capacitor Cst is VREF−Vdata_H+Vt1.

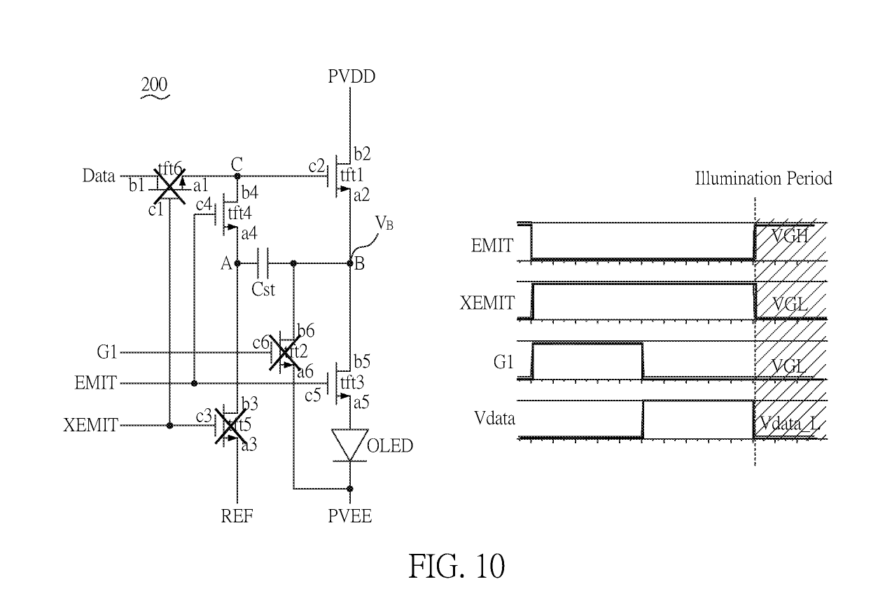

FIG. 10 is a schematic diagram of the illumination period of the pixel circuitry 200 of FIG. 7 of the present disclosure. Referring to FIG. 10, during a illumination period, the first control signal source XEMIT outputs low control voltage VGL, the second control signal source EMIT outputs the high control voltage VGH, and the third control signal source G1 outputs the low control voltage VGL.

During the illumination period, since the first control signal source XEMIT outputs the low control voltage VGL, the compensating transistor tft5 and the data transistor tft5 may be turned off. The third control signal source G1 may output the low control voltage VGL, and the reset transistor tft2 may be turned off. Because the second control signal source EMIT outputs high control voltage VGH, the first control transistor tft4 and the second control transistor tft3 may be turned on. Since the first control transistor tft4 is turned on, the voltage at node C may equal to the voltage at node A, and the driving transistor tft1 may be turned on.

During this time, an electrical path is formed between the high voltage source PVDD and the low voltage source PVEE. The voltage at node B is determined by the resistance of the driving transistor tft1, the second control transistor tft3 and the organic light-emitting diode element OLED. The voltage at node B is labeled as V_{B}, and V_{B}=[(PVDD−PVEE)*(R2+R3)/(R1+R2+R3)]+PVEE, where PVDD is the output voltage of the high voltage source PVDD, PVEE is the output voltage of the low voltage source PVEE, R1 is the resistance of the driving transistor tft1 while the driving transistor tft1 is turned on, R2 is the resistance of the second control transistor tft3 while the second control transistor tft3 is turned on, and R3 is the resistance of the organic light-emitting diode element OLED while the organic light-emitting diode OLED element is turned on. Since the voltage at the driving transistor tft1 and the second control transistor tft3 can be regarded as constant, the voltage V_{B} at node B can be regarded as the voltage of the organic light-emitting diode element OLED.

Since the voltage at node A equals to the voltage at node B plus the voltage in the storage capacitor Cst, the voltage at node A is V_{B}+VREF−Vdata_H+Vt1. Similarly, the voltage at node C is V_{B}+VREF−Vdata_H+Vt1. Therefore, the gate-source voltage Vgs_tft1 of the driving transistor tft1 is the voltage at node C minus the voltage at node B. Hence, the gate-source voltage Vgs_tft1 of the driving transistor is (V_{B}+VREF−Vdata_H+Vt1)−V_{B}=VREF−Vdata_H+Vt1. In other words, the potential difference between both sides of the storage capacitor is VREF−Vdata_H+Vt1. It can be appreciated that the voltage V_{B} at node B does not appear in the equation for the current, and thus does not affect the current.

Therefore, during the illumination period, the current of the driving transistor tft1 is:

$$\begin{matrix}{{I}_{\_}}_{tft 1} = {{I}_{\_}}_{OLED} \\ = Kpn * {[ Vgs\_tft 1 - Vt 1 ]}^{2} \\ = Kpn * {[ ( VREF - Vdata\_H + Vt 1 ) - Vt 1 ]}^{2} \\ = Kpn * {[ VREF - Vdata\_H ]}^{2} ,\end{matrix}$$

where Kpn is the transistor transconductance parameter of the driving transistor tft1, Kpn=½*u*Cox*W/L; u is the charge carrier mobility of the semiconductor, Cox is the capacitance per unit area, and W/L is the transistor width-length ratio.

From the equations above, it can be appreciated that during the illumination period, the current I__{^{tft1}} of the driving transistor tft1 is not affected by the threshold voltage Vt1 of the driving transistor tft1. Therefore, the current I__{^{tft1}} of the driving transistor tft1 is not affected by the localized threshold voltage variation that is caused by the fabrication process or any other factors. For two N type driving transistors of the same size, with the technique of the present disclosure, when the same driving voltage is applied thereto, the output currents from the driving transistors may be the same as each other, thereby solving problems such as uneven brightness (mura) or bad uniformity.

Furthermore, according to the equation for current, Vdata_H is the high data voltage for a display data written by the data line Data, i.e. Vdata_H corresponds to the current of the organic light-emitting diode element OLED, or Vdata_H corresponds to the brightness of the organic light-emitting diode element OLED; therefore, by writing in a voltage value of the display data, the brightness of the organic light-emitting diode element OLED can be changed. In addition, it can be appreciated from the equation for current that the brightness of the organic light-emitting diode element OLED can be changed via the voltage VREF of the reference signal REF. The voltage VREF of the reference signal REF is a global parameter. In other words, when the voltage VREF of the reference signal REF is reduced, the brightness of the LED display panel 100 may be decreased; when the voltage VREF of the reference signal REF is increased, the brightness of the LED display panel 100 may be increased.

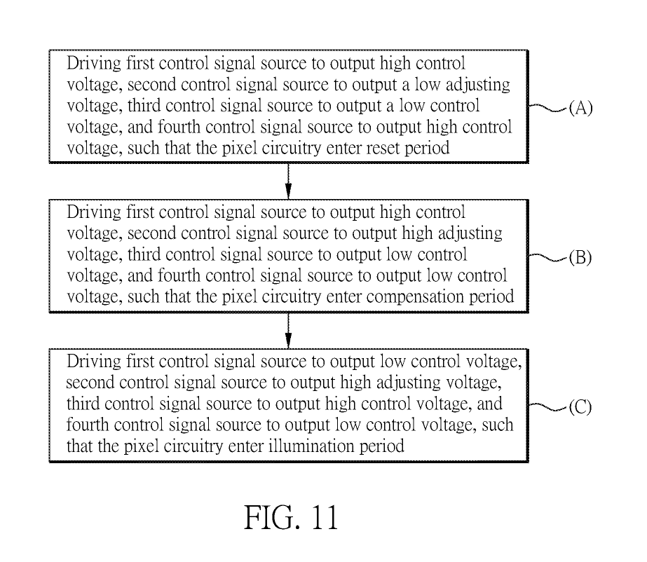

FIG. 11 is a flowchart for the driving method of the LED display panel of the present disclosure. Reference should also be made to the schematic diagram of LED display panel in FIG. 1, and the circuit diagram of the pixel circuitry in FIG. 2 of the present disclosure. The LED display panel 100 may be disposed with a plurality of wirings and pixel circuitries 200 that correspond to each other and are electrically connected; the pixel circuitries 200 may be arranged in rows and columns. The method is to control each pixel circuitry 200 with a first control signal source G2, a second control signal source VI, a third control signal source EMIT and a fourth control signal source G1. The first control signal source G2, second control signal source VI, third control signal source EMIT, and fourth control signal source G1 may generate their respective control signal sequentially, such that the pixel circuitry 200 has a reset period, a compensation period, and a illumination period. The reset period, the compensation period, and the illumination period may operate independently.

Step A: driving the first control signal source G2 to output a high control voltage VGH, driving the second control signal source VI to output a low adjusting voltage VI_L, driving the third control signal source EMIT to output a low control voltage VGL, and driving the fourth control signal source G1 to output the high control voltage VGH, such that the pixel circuitry 200 enter a reset period. The high control voltage VGH may be higher than the voltage of the high voltage source PVDD. The low adjusting voltage VI_L may be higher than the voltage of the low voltage source PVEE. The low voltage source PVEE may be higher than the voltage of the low control voltage VGL.

During the reset period, the data transistor tft6, the compensating transistor tft5, and the reset transistor tft2 may be turned on, and voltages at both terminals of the storage capacitor Cst may respectively be Vdata and PVEE, where Vdata is a voltage for a display data written by the data line Data, and PVEE is a voltage of the low voltage source. In other words, as shown in FIG. 2, the voltage at node A is Vdata while the voltage at node B is PVEE. The first control transistor tft4 and the second control transistor tft3 may be turned off. The compensating transistor tft5 may be turned on, and the voltage at node C may be the low adjusting voltage VI_L. In order to turn off the driving transistor tft1, the value of the low adjusting voltage VI_L has to be smaller than the sum of the low voltage source PVEE and the threshold voltage Vt1 of the driving transistor tft1, so as to prevent the current leakage from occurring in the organic light-emitting diode element OLED, and hence dark-state light leakage and power consumption issues of the organic light-emitting diode element OLED can be avoided. The low adjusting voltage VI_L is higher than the low control voltage VGL, and the low adjusting voltage VI_L is lower than the sum of voltage of the low voltage source PVEE and the threshold voltage Vt1 of the driving transistor tft1. So, the low adjusting voltage VI_L satisfies the relationship VGL<VI_L<PVEE+Vt1.

Step B: driving the first control signal source G2 to output a high control voltage VGH, driving the second control signal source VI to output a high adjusting voltage VI_H, driving the third control signal source EMIT to output a low control voltage VGL, and driving the fourth control signal source G1 to output the low control voltage VGL, such that the pixel circuitry 200 enter a compensation period.

During the compensation period, the compensating transistor tft5 and the data transistor tft6 may be turned on, and the second control transistor tft3 and the reset transistor tft2 may be turned off. The compensating transistor tft5 may be turned on and the first control transistor tft4 may be turned off; therefore the voltage at node C in FIG. 2 is the high adjusting voltage Vl_H, and this turns the driving transistor tft1 on. Therefore as shown in FIG. 2, the voltage at node B is Vl_H−Vt1, where Vl_II is the high adjusting voltage of the second control signal source Vl, and Vt1 is the threshold voltage of the driving transistor tft1. As shown in FIG. 2, since the data transistor tft6 is turned on, the voltage at node A is Vdata. Therefore, the voltages at both sides of the storage capacitor Cst are Vdata and VI_H−Vt1 respectively. The voltage in the storage capacitor Cst is Vdata−VI_H+Vt1. In other words, during the compensation period, the storage capacitor Cst in each pixel circuitry may store the voltage Vdata of the display data, the threshold voltage Vt1 of the driving transistor tft1, and high adjusting voltage VI_H of the control signal VI.

Step C: driving the first control signal source G2 to output a low control voltage VGL, driving the second control signal source VI to output a high adjusting voltage VI_H, driving the third control signal source EMIT to output a high control voltage VGH, and driving the fourth control signal source G1 to output the low control voltage VGL, such that the pixel circuitry 200 enter a illumination period.

During the illumination period, the compensating transistor tft5, data transistor tft6, and reset transistor tft2 may be turned off. The first control transistor tft4, second control transistor tft3, and driving transistor tft1 may be turned on. The voltage in the storage capacitor Cst is Vdata−VI_H+Vt1, where Vdata is the voltage for display data written by the data line, Vl_H is the high adjusting voltage of the second control signal source Vl, and Vt1 is the threshold voltage of the driving transistor tft1. The current of the driving transistor tft1 is:

I__{^{tft1}}=I__{^{OLED}}=Kpn*[Vdata−VI_H]²,

where Kpn is the transistor transconductance parameter of the driving transistor tft1, Kpn=½*u*Cox*W/L; u is the charge carrier mobility of the semiconductor, Cox is the capacitance per unit area, and W/L is the transistor width-length ratio. In other words, during the illumination period, the current I__{^{tft1}} of the driving transistor tft1 is not affected by the threshold voltage Vt1 of the driving transistor tft1.

Apparently, with the technique of the present disclosure, the current of the driving transistor is not affected by the threshold voltage of the driving transistor. Therefore, the current of the driving transistor is less likely to be affected by the variation of threshold voltage. Therefore, for two N type driving transistors of the same size, when the same driving voltage is applied thereto, the output currents from the driving transistors may be the same as each other, thereby solving problems such as uneven brightness (mura) or bad uniformity.

Although the present disclosure has been explained in relation to its preferred embodiment, it is understood that many other possible modifications and variations can be made without departing from the spirit and scope of the disclosure as hereinafter claimed.

What is claimed is:

1. A display panel comprising a plurality of pixel circuitries, wherein at least one pixel circuitry comprises:
a data transistor comprising a control terminal connected to a first control signal source, a first terminal connected to a data line, and a second terminal;
a driving transistor comprising a control terminal, a first terminal, and a second terminal connected to a high voltage source;
a storage capacitor connected to the second terminal of the data transistor and the first terminal of the driving transistor;
a compensating transistor comprising a control terminal connected to the first control signal source, a first terminal connected to the control terminal of the driving transistor, and a second terminal connected to a second control signal source;
a first control transistor comprising a control terminal connected to a third control signal source, a first terminal connected to the second terminal of the data transistor, and a second terminal connected to the control terminal of the driving transistor; and
a second control transistor comprising a control terminal connected to the third control signal source, a first terminal connected to an organic light-emitting diode element, and a second terminal connected to the first terminal of the driving transistor.

2. The display panel of claim 1, wherein the at least one circuitry further comprises a reset transistor comprising a control terminal connected to a fourth control signal source, a first terminal connected to the first terminal of the driving transistor, and a second terminal connected to a low voltage source.

3. The display panel of claim 2, wherein the data transistor, the driving transistor, the compensating transistor, the first control transistor, the second control transistor, and the reset transistor are N-type transistors.

4. The display panel of claim 2, wherein the data transistor, the driving transistor, the compensating transistor, the first control transistor, the second control transistor, and the reset transistor are made of N-type low temperature poly-silicon (LTPS), N-type indium gallium zinc oxide (IGZO), or N-type amorphous silicon.

5. The display panel of claim 2, wherein during a reset period, the data transistor, the compensating transistor, and the reset transistor are turned on, the driving transistor, and the first control transistor, and the second control transistor are turned off.

6. The display panel of claim 5, wherein voltages at both terminals of the storage capacitor are respectively Vdata and PVEE, where Vdata is a voltage for a display data written by the data line, and PVEE is a voltage of the low voltage source.

7. The display panel of claim 2, wherein during a compensation period, the driving transistor, the compensating transistor, and the data transistor are turned on, and the reset transistor, the first control transistor, and the second control transistor are turned off.

8. The display panel of claim 7, wherein voltages at both terminals of the storage capacitor are respectively Vdata and VI_H−Vt1, where Vdata is a voltage for a display data written by the data line, VI_H is a high adjusting voltage from the second control signal source, and Vt1 is a threshold voltage of the driving transistor.

9. The display panel of claim 2, wherein each of the first control signal source and fourth control signal source is adapted to supply a high control voltage and a low control voltage, the second control signal source is adapted to supply a high adjusting voltage and a low adjusting voltage, the high control voltage is higher than a voltage of the high voltage source, the voltage of the high voltage source is higher than the high adjusting voltage, the low adjusting voltage is higher than a voltage of the low voltage source, and the voltage of the low voltage source is higher than the low control voltage.

10. A display panel comprising a plurality of pixel circuitries, wherein at least one pixel circuitry comprises:
a data transistor comprising a control terminal connected to a first control signal source, a first terminal, and a second terminal connected to a data line;
a driving transistor comprising a control terminal connected to the first terminal of the data transistor, a first terminal, and a second terminal connected to a high voltage source;
a compensating transistor comprising a control terminal connected to the first control signal source, a first terminal connected to a reference signal, and a second terminal;
a first control transistor comprising a control terminal connected to a second control signal source, a first terminal connected to the second terminal of the compensating transistor, and a second terminal connected to the control terminal of the driving transistor; and
a storage capacitor connected to the second terminal of the compensating transistor and the first terminal of the driving transistor;
a second control transistor comprising a control terminal connected to the second control signal source, a first terminal connected to an organic light-emitting diode element, and a second terminal connected to the first terminal of the driving transistor; and
a reset transistor comprising a control terminal connected to a third control signal source, a first terminal connected to a low voltage source, and a second terminal connected to the first terminal of the driving transistor.

11. The display panel of claim 10, wherein the data transistor, the driving transistor, the compensating transistor, the first control transistor, the second control transistor, and the reset transistor are N-type transistors.

12. The display panel of claim 10, wherein the data transistor, the driving transistor, the compensating transistor, the first control transistor, the second control transistor, and the reset transistor are made of N-type low temperature poly-silicon (LTPS), N-type indium gallium zinc oxide (IGZO), or N-type amorphous silicon.

13. The display panel of claim 10, wherein during a reset period, the data transistor, the compensating transistor, and the reset transistor are turned on, and the driving transistor, the first control transistor, and the second control transistor are turned off.

14. The display panel of claim 13, wherein voltages at both terminals of the storage capacitor are respectively VREF and PVEE, where VREF is a voltage for the reference signal, and PVEE is a voltage of the low voltage source.

15. The display panel of claim 10, wherein during a compensation period, the driving transistor, the compensating transistor, and the data transistor are turned on, and the reset transistor, the first control transistor, and the second control transistor are turned off.

16. The display panel of claim 15, wherein voltages at both terminals of the storage capacitor are respectively VREF and Vdata_H−Vt1, where VREF is a voltage for the reference signal, Vdata_H is a high data voltage for a display data written by the data line, and Vt1 is a threshold voltage of the driving transistor.
